(19) United States
(12) Patent Application Publication
(10) Pub. No.: US 2012/0196425 A1
(43) Pub. Date: Aug. 2, 2012

(54) High-K Metal Gate Electrode Structures Formed by a Replacement Gate Approach Based on Superior Planarity of Placeholder Materials

(75) Inventors: Thilo Scheiper, Dresden (DE); Andy Wei, Dresden (DE); Stefan Flachowsky, Dresden (DE); Jan Hoentschel, Dresden (DE)

(73) Assignee: GLOBALFOUNDRIES INC., Grand Cayman (KY)

(21) Appl. No.: 13/354,613

(22) Filed: Jan. 20, 2012

(30) Foreign Application Priority Data
Jan. 27, 2011 (DE) 10 2011 003 232.0

(51) Int. Cl. H01L 21/762; H01L 21/28

(52) U.S. Cl. 438/400; 438/585; 257/E21.19; 257/E21.545

(57) ABSTRACT

When forming sophisticated high-k metal gate electrode structures on the basis of a replacement gate approach, superior process uniformity may be achieved by implementing at least one planarization process after the deposition of the placeholder material, such as the polysilicon material, and prior to actually patterning the gate electrode structures.

### BACKGROUND OF THE INVENTION

1. Field of the Invention

Generally, the present disclosure relates to the fabrication of sophisticated integrated circuits including transistor elements comprising gate structures on the basis of a high-k gate dielectric material and a work function metal provided in a late manufacturing stage.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout, wherein field effect transistors represent one important type of circuit element that substantially determines performance of the integrated circuits. Generally, a plurality of process technologies are currently practiced, wherein, for many types of complex circuitry, including field effect transistors, CMOS technology is currently one of the most promising approaches due to the superior characteristics in view of operating speed and/or power consumption and/or cost efficiency. During the fabrication of complex integrated circuits using, for instance, CMOS technology, millions of transistors, i.e., N-channel transistors and P-channel transistors, are formed on a substrate including a crystalline semiconductor layer. A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed adjacent to the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a given extension of the channel region in the transistor width direction, the distance between the source and drain regions, which is also referred to as channel length. Hence, the conductivity of the channel region substantially affects the performance of MOS transistors. Thus, the reduction of channel resistivity is a dominant design criterion for accomplishing an increase in the operating speed of the integrated circuits.

Presently, most integrated circuits are based on silicon due to substantially unlimited availability, the well-understood characteristics of silicon and related materials and processes and the experience gathered during the last 50 years. Therefore, silicon will likely remain the material of choice for future circuit generations designed for mass products. One reason for the importance of silicon in fabricating semiconductor devices has been the superior characteristics of a silicon/silicon dioxide interface that allows reliable electrical insulation of different regions from each other. The silicon/silicon dioxide interface is stable at high temperatures and, thus, allows the performance of subsequent high temperature processes, as are required, for example, for anneal cycles to activate dopants and to cure crystal damage without sacrificing the electrical characteristics of the interface.

For the reasons pointed out above, in field effect transistors, silicon dioxide is preferably used as a base material of a gate insulation layer that separates the gate electrode, frequently comprised of polysilicon or metal-containing materials, from the silicon channel region. In steadily improving device performance of field effect transistors, the length of the channel region has been continuously decreased to improve switching speed and drive current capability. Since the transistor performance is controlled by the voltage supplied to the gate electrode to invert the surface of the channel region to a sufficiently high charge density for providing the desired drive current for a given supply voltage, a certain degree of capacitive coupling, provided by the capacitor formed by the gate electrode, the channel region and the silicon dioxide disposed therebetween, has to be maintained. It turns out that decreasing the channel length requires an increased capacitive coupling to avoid the so-called short channel behavior during transistor operation. The short channel behavior may lead to an increased leakage current and to a pronounced dependence of the threshold voltage on the channel length. Aggressively scaled transistor devices with a relatively low supply voltage, and thus reduced threshold voltage, may suffer from an exponential increase of the leakage current, while also requiring enhanced capacitive coupling of the gate electrode to the channel region. Thus, the thickness of the silicon dioxide layer has to be correspondingly decreased to provide the required capacitance between the gate and the channel region. For example, a channel length of approximately 0.08 μm may require a gate dielectric made of silicon dioxide as thin as approximately 1.2 nm. In this case, the relatively high leakage current caused by direct tunneling of charge carriers through an ultra-thin silicon dioxide gate insulation layer may reach values for an oxide thickness in the range of 1-2 nm that may not be compatible with thermal design power requirements for performance-driven circuits.

Therefore, replacing silicon dioxide-based dielectrics as the material for gate insulation layers has been considered, particularly for extremely thin silicon dioxide-based gate layers. Possible alternative materials include materials that exhibit a significantly higher permittivity so that a physically greater thickness of a correspondingly formed gate insulation layer provides a capacitive coupling that would be obtained by an extremely thin silicon dioxide layer.

Additionally, transistor performance may be increased by providing an appropriate conductive material for the gate electrode so as to replace the usually used polysilicon material, since polysilicon may suffer from charge carrier depletion at the vicinity of the interface to the gate dielectric, thereby reducing the effective capacitance between the channel region and the gate electrode. Thus, a gate stack has been suggested in which a high-k dielectric material provides enhanced capacitance, while additionally maintaining leakage currents at an acceptable level. On the other hand, the non-polysilicon material, such as titanium nitride and the like, in combination with other metals, may be formed so as to connect to the high dielectric material, thereby substantially avoiding the presence of a depletion zone. Since the threshold voltage of the transistors, which represents the voltage at which a conductive channel forms in the channel region, is significantly determined by the work function of the metal-containing gate material, an appropriate adjustment of the effective work function with respect to the conductivity type of the transistor under consideration has to be guaranteed.

Providing different metal species for adjusting the work function of the gate electrode structures for P-channel transistors and N-channel transistors at an early manufacturing stage may, however, be associated with a plurality of difficulties, which may stem from the fact that a complex patterning sequence may be required during the formation of the sophisticated high-k metal gate stack, which may result in a significant variability of the resulting work function and thus threshold of the completed transistor structures. For instance, during a corresponding manufacturing sequence, the high-k material may be exposed to oxygen, which may result in an increase of layer thickness and thus a reduction of the capacitive coupling. Moreover, a shift of the work function may be observed when forming appropriate work function metals in an early manufacturing stage, which is believed to be caused by a moderately high oxygen affinity of the metal species, in particular during high temperature processes which may typically be required for completing the transistor structures, for instance for forming drain and source regions and the like.

For this reason, in other approaches, the initial gate electrode stack may be provided with a high degree of compatibility with conventional polysilicon-based process strategies and the actual electrode metal and the final adjustment of the work function of the transistors may be accomplished in a very advanced manufacturing stage, i.e., after completing the basic transistor structure. In a corresponding replacement, a standard polysilicon or amorphous silicon material is patterned on the basis of well-established advanced lithography and etch techniques. After patterning the gate electrode structure, conventional and well-established process techniques for forming the drain and source regions having the desired complex dopant profile are typically performed. After any high temperature processes, the further processing may be continued, for instance by forming a metal silicide, if required, followed by the deposition of an interlayer dielectric material, such as silicon nitride in combination with silicon dioxide and the like. In this manufacturing stage, a top surface of the gate electrode structures embedded in the interlayer dielectric material may be exposed, for instance, by etch techniques, chemical mechanical polishing (CMP) and the like. Thereafter, the polysilicon material is removed in the gate electrode structures and an appropriate masking regime may be applied in order to fill in a high-k dielectric material, if not already formed in an earlier phase, and to selectively fill in an appropriate work function metal and an electrode metal.

Although generally this approach may provide advantages in view of reducing process-related non-uniformities of the threshold voltages of the transistors, since sensitive materials, such as work function metal species and the like, may be provided in a very late manufacturing stage, i.e., after any high temperature processes, the process for removing the placeholder material, such as the polysilicon material, may, however, be associated with irregularities, which may result in significant variations of planar transistors and non-planar transistors, such as FinFETS and the like, as will be described in more detail with reference to FIGS. 1a-1g and 2a-2e.

FIG. 1a schematically illustrates a top view of a semiconductor device 100 in which planar transistors 150A, 150B may comprise a common gate electrode structure 160. As shown, the transistors 150A, 150B are formed in and above corresponding active regions 102A, 102B, respectively, which are separated and also laterally delineated by an isolation region 102C, which in the present example is provided in the form of a shallow trench isolation. It should be appreciated that the semiconductor device 100 may represent a sophisticated semiconductor device in which the gate electrode structure 160 is to be provided on the basis of a replacement gate approach, as is also described above.

FIG. 1b schematically illustrates a cross-sectional view along the line W of FIG. 1a and thus represents a cross-sectional view of the width direction of the device 100. That is, the semiconductor regions or active regions 102A, 102B are shown in a cross-sectional view, in which the horizontal direction of FIG. 1b corresponds to a width direction, while a direction perpendicular to the drawing plane of FIG. 1b may represent the transistor length direction. In the manufacturing stage shown, the semiconductor device 100 comprises a substrate 101, such as a silicon substrate, possibly in combination with a buried insulating layer (not shown), when a silicon-on-insulator (SOI) configuration is used. Moreover, the active regions 102A, 102B are separated and also laterally delineated by the isolation region 102C. It should be appreciated that the isolation region 102C and the semiconductor regions 102A, 102B are considered as being part of a semiconductor layer 102, such as a silicon layer, which represents a continuous semiconductor material at an initial manufacturing stage in which subsequently the isolation structure 102C is formed so as to define the lateral size, shape and position of the active regions 102A, 102B. Furthermore, a gate dielectric material 161, such as a silicon dioxide-based material, is formed at least above the active regions 102A, 102B and, depending on the process for forming the material 161, also above the isolation region 102C (not shown). Moreover, a polysilicon layer 162 is formed above the semiconductor layer 102 comprising the semiconductor regions 102A, 102B and the isolation region 102C.

Typically, the semiconductor device 100 as illustrated in FIG. 1b is formed on the basis of the following processes. The semiconductor layer 102 is subjected to sophisticated lithography, etch, deposition, anneal and planarization techniques and the like in order to form the isolation region 102C. During the complex process sequence, typically a more or less pronounced difference in the corresponding height levels between the active regions 102A, 102B and the isolation region 102C, as indicated by 102H, is generated, which may significantly affect the further processing with respect to applying a replacement gate approach, as will be discussed later on in more detail. After the removal of any sacrificial material layers (not shown), thereby obtaining the pronounced surface topography as shown in FIG. 1b, the gate dielectric layer 161 is formed, for instance, by oxidation and the like. Next, the polysilicon material 162 is deposited, for instance by using well-established low pressure chemical vapor deposition (CVD) techniques. Consequently, the surface of the layer 162 may have a topography that is determined by the topography caused by the active regions 102A, 102B and the isolation region 102C. It should be appreciated that, in particular for the closely spaced active regions 102A, 102B, the pronounced step 102H may result in significant irregularities for a gate electrode structure to be formed so as to extend across the active regions 102A, 102B and bridging the isolation region 102C.

FIG. 1c schematically illustrates the device 100 with a further material layer 163 formed above the polysilicon layer 162. The layer 163 may represent a layer or layer system which may be used as an efficient hard mask material during the complex patterning process for forming a gate electrode structure from the layer 162. For example, the layer 163 may be comprised of silicon nitride, possibly in combination with appropriate etch stop liners (not shown) provided in the form of silicon dioxide and the like. Next, a complex patterning strategy is applied in which, for instance, in a first process sequence, the layer or layers 163 are patterned into an appropriate hard mask, which is then used for etching through the polysilicon layer 162 in order to obtain the desired lateral dimensions of the gate electrode structure 160 as shown in the top view of FIG. 1a. Consequently, due to the initial pronounced surface topography, the step-like topography between the active regions 102A, 102B is still present in the gate electrode structure formed from the layers 163 and 162.

Thereafter, the processing is continued by performing any process techniques as required for completing the transistor elements 150A, 150B (FIG. 1a), for instance using implantation techniques in combination with appropriate masking regimes, while also a spacer structure (not shown) may be provided so as to appropriately adjust the lateral and vertical dopant profiles in the active regions 102A, 102B. After any high temperature processes, the further processing is continued by providing an interlayer dielectric material.

FIG. 1d schematically illustrates the device 100 in this manufacturing stage. Thus, as illustrated, appropriate dielectric materials 121, 122, for instance in the form of silicon nitride and silicon dioxide, are formed above and laterally adjacent to the gate electrode structure 160, which still comprises the dielectric hard mask or cap layer 163 in combination with the polysilicon material 162. The layers 121, 122 are deposited on the basis of well-established deposition techniques, such as plasma enhanced CVD, high density plasma CVD, sub-atmospheric CVD and the like. In this manufacturing stage, a complex removal process based on a CMP process is applied so as to expose the polysilicon material 162 of the gate electrode structure 160 in order to replace this material with appropriate electrode materials, such as aluminum and the like. Consequently, during the removal process, a plurality of different materials have to be polished, while, at the final phase of the removal process, the materials of the layers 121 and of the cap layer 163 have to be removed.

FIG. 1e schematically illustrates the device 100 after a corresponding removal process, thereby obtaining a substantially planar surface 162S, which corresponds to the surface of the gate electrode structure 160 and to any interlayer dielectric material (not shown) that are added laterally adjacent to the gate electrode structure 160. As illustrated, due to the pronounced surface topography between the active regions 102A, 102B, residues 163R of at least the cap layer 163 (FIG. 1d) may remain. It turns out that any such residues 163R may still be present after applying a certain over-polish time, while further increasing the over-polish time would significantly reduce the overall height of the gate electrode structure 160, which in turn may not be compatible with the further processing of the device 100.

FIG. 1f schematically illustrates the device 100 during a selective etch process 104, typically performed on the basis of a highly selective wet chemical etch chemistry in order to remove the polysilicon material 162 selectively with respect to silicon dioxide, silicon nitride and the like, which are typically provided laterally adjacent to the gate electrode structure 160. Consequently, during the etch process 104, the presence of the material residues 163R may result in an incomplete removal of the polysilicon material 162 above the isolation region 102C, as is indicated by 162R. Consequently, during the further processing, i.e., the position of at least appropriate electrode materials, the remaining portion 162R may result in significantly different electronic characteristics of the gate electrode structure 160.

FIG. 1g schematically illustrates the device 100 in a manufacturing phase in which at least a highly conductive electrode metal 165, such as aluminum, is filled into the gate openings, which have been obtained by removing the polysilicon material 162 (FIG. 1e). To this end, any well-established metal deposition techniques may be applied. However, as shown in FIG. 1g, the residues 162R in combination with the residues 163R may represent a high ohmic electrode portion in the gate electrode structure 160, thereby significantly altering the overall electrical performance of the gate electrode structure 160. Consequently, high ohmic behavior of the gate electrode structure 160 may significantly affect overall device performance, which may even result in a total failure of the semiconductor device 100.

FIG. 2a schematically illustrates a top view of a semiconductor device 200 which may be a part of the device 100 or which may be provided as a separate semiconductor device. As shown, a transistor 250 in the form of a non-planar transistor device, also referred to as FinFET, is formed in a semiconductor layer 202 and comprises drain and source regions 202D, 202S, respectively, which are connected by corresponding semiconductor fins 210, which may thus represent appropriate channel regions that are laterally enclosed and which are also covered by a gate electrode structure 260. Furthermore, the transistor 250 may be appropriately laterally delineated by an isolation region 202C.

FIG. 2b schematically illustrates a cross-sectional view corresponding to the section W of FIG. 2a in an early manufacturing stage. Also in this case, a section of FIG. 2b may represent a section along the “width” direction, i.e., in FIG. 2b, the horizontal direction, while a current flow direction or transistor length direction is oriented perpendicularly to the drawing plane of FIG. 2b. As shown, the device 200 comprises the plurality of semiconductor fins 210, which may represent a comb-like structure of the semiconductor layer 202, which is laterally delineated by the isolation region 202C. Furthermore, isolation regions 205 are also formed between the semiconductor fins 210 in order to actually delimit the effective electrical height of the fins 210. For example, the isolation regions 205 are provided in the form of a silicon dioxide material. For example, the device 200 as shown in FIG. 2b may be formed by patterning the fins 210 prior to or after forming the isolation region 202C by applying complex and sophisticated etch techniques. Thereafter, the isolation regions 205 may be formed, for instance, by filling in an oxide material and etching the oxide material down to a desired height level.

FIG. 2c schematically illustrates the device 200 in a further advanced manufacturing stage. As shown, a gate dielectric material 261, such as a silicon dioxide material, may be formed on surface areas of the semiconductor fins 210, for instance by oxidation, deposition and the like. Furthermore, a polysilicon material 262, as a placeholder material, is formed above and in between the semiconductor fins 210. Furthermore, a dielectric cap layer 263 may be provided, for instance in the form of a silicon nitride material and the like. Thereafter, appropriate lithography techniques are applied so as to form an etch mask, for instance from the layer 263, and to pattern the polysilicon material 262 in order to obtain the desired lateral size, as is for instance shown in the top view of FIG. 2a. It should be appreciated that the pronounced surface topography caused by the semiconductor fins 210 may also result in a pronounced surface topography in the layers 262 and 263, thereby preserving this surface topography after the patterning of the materials 263 and 262.

Thereafter, any further process techniques are applied, for instance for incorporating dopant species, forming a spacer structure (not shown), performing anneal processes and the like, in order to complete the basic transistor configuration. Next, an interlayer dielectric material may be formed above and adjacent to the gate electrode structure 260, for instance in the form of the materials 221 and 222, such as a silicon nitride material and a silicon dioxide material. Thereafter, a planarization process is performed in order to finally expose the polysilicon material 262, which is to be replaced by at least a conductive electrode material, as is also discussed above with reference to the device 100 when referring to a planar transistor configuration.

FIG. 2d schematically illustrates the device 200 in a further advanced manufacturing stage. As shown, a substantially planar surface 262S may be obtained in the gate electrode structure 260 and also in the adjacent interlayer dielectric materials, (not shown), wherein, however, due to the previously induced surface topography, residues 263R may still be present in the gate electrode structure 260, which may also result in significant irregularities during the further processing.

FIG. 2e schematically illustrates the device 200 after completing the replacement gate approach in which a highly conductive electrode metal 265 is provided in the gate electrode structure 260, which may be accomplished on the basis of the same process strategies as discussed above with reference to the device 100 when referring to the planar transistor configuration. That is, upon removing the polysilicon material on the basis of highly selective etch recipes, the residues 263R may result in an incomplete removal of the polysilicon material, as indicated by the residues 262R. Consequently, after filling in the highly conductive material 265 and removing any excess material thereof, the residues 262R, 263R may significantly affect the overall electrical performance of the gate electrode structure 260.

Since a corresponding deterioration of electrical performance of sophisticated high-k metal gate electrode structures may offset many of the advantages obtained by the superior gate configuration, in particular when highly scaled semiconductor devices are considered, the conventional process strategy may result in significant yield losses when producing sophisticated semiconductor devices based on planar and/or non-planar transistor configurations using a replacement gate approach.

In view of the situation described above, the present disclosure relates to manufacturing techniques for forming sophisticated high-k metal gate electrode structures on the basis of a replacement gate approach, while avoiding or at least reducing the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides manufacturing techniques in which sophisticated high-k metal gate electrode structures may be formed on the basis of a replacement gate approach, wherein superior process efficiency may be accomplished by reducing a surface topography prior to actually patterning complex placeholder electrode structures, such as placeholder electrode structures for planar transistors or placeholder electrode structures for non-planar transistor architectures, which will be referred to hereinafter as FinFET devices. To this end, an efficient planarization may be applied during and/or after the deposition of the placeholder material, such as a polysilicon material, so that any subsequent deposition of further materials may be accomplished on the basis of a substantially planar surface topography. Hence, in a very advanced manufacturing stage, the removal of any dielectric materials and, thus, the exposure of the top surface of the placeholder material may be accomplished with superior efficiency, thereby avoiding or at least significantly reducing the probability of creating material residues, which in turn may negatively affect the further processing, as is the case in the conventional process strategy.

One illustrative method disclosed herein comprises forming a layer of a placeholder material above a semiconductor layer of a semiconductor device, wherein the semiconductor layer comprises a first semiconductor region and a second semiconductor region that are laterally separated by an isolation region. The method further comprises performing a planarization process so as to form a planarized surface on the layer of placeholder material. Additionally, the method comprises forming a placeholder electrode structure from at least the layer of a placeholder material, wherein the placeholder electrode structure is formed above the first and second semiconductor regions and above the isolation region. Moreover, the method comprises replacing the placeholder material of the placeholder electrode structure, at least with a conductive electrode material, so as to form a gate electrode structure.

A further illustrative method disclosed herein relates to forming gate electrode structures. The method comprises forming a placeholder material above a first semiconductor region, a second semiconductor region and an isolation region that laterally delineates the first and second semiconductor regions. The method further comprises planarizing the placeholder material so as to form a substantially planarized surface of the placeholder material above the first and second semiconductor regions and above the isolation region. Additionally, the method comprises patterning the place holder material that has the substantially planarized surface so as to form a placeholder electrode structure. Moreover, an interlayer dielectric material is formed above the placeholder material and a material removal process is performed so as to expose a top surface of the placeholder material. Additionally, the method comprises replacing the placeholder material at least with an electrode material.

A still further illustrative method disclosed herein comprises forming a plurality of semiconductor fins so as to be laterally separated by isolation regions, wherein the plurality of semiconductor fins extend to a first height level and wherein the isolation regions extend to a second height level that is less than the first height level. The method further comprises forming a placeholder material above the plurality of semiconductor fins and the isolation regions. Additionally, the method comprises planarizing the placeholder material and patterning the planarized placeholder material so as to form a placeholder electrode structure. Furthermore, an interlayer dielectric material is formed above the placeholder electrode structure and a top structure of the placeholder material is exposed. Additionally, the placeholder material is replaced at least with an electrode material.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a top view of a semiconductor device comprising a planar transistor architecture receiving a gate electrode structure on the basis of a replacement gate approach, according to conventional strategies;

FIGS. 1b-1g schematically illustrate cross-sectional views along the transistor width direction during various manufacturing stages in forming replacement gate electrode structures, according to conventional techniques;

FIG. 2a schematically illustrates a top view of a FinFET configuration that receives a replacement gate electrode structure, according to conventional process strategies;

FIGS. 2b-2e schematically illustrate cross-sectional views along a transistor width direction during various manufacturing stages in applying a replacement gate approach, according to conventional strategies;

FIGS. 3a-3c schematically illustrate cross-sectional views along a width direction during various manufacturing stages in forming sophisticated high-k metal gate electrode structures with superior surface topography, according to illustrative embodiments;

FIG. 3d schematically illustrates a cross-sectional view along the transistor length direction after patterning a sophisticated placeholder gate electrode structure, according to illustrative embodiments;

FIGS. 3e-3f schematically illustrate cross-sectional views of the semiconductor device in further advanced manufacturing stages, according to illustrative embodiments;

FIGS. 3g-3h schematically illustrate cross-sectional views along the transistor length direction during various manufacturing stages in replacing a placeholder material with at least a conductive electrode material, according to illustrative embodiments;

FIG. 3i schematically illustrates the replacement gate electrode structure in a sectional view along the transistor width direction, according to illustrative embodiments; and

FIGS. 4a-4c schematically illustrate cross-sectional views along a transistor width direction of a FinFET during various manufacturing stages in forming sophisticated high-k metal gate electrode structures, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally contemplates manufacturing techniques in which sophisticated high-k metal gate electrode structures may be formed on the basis of a replacement gate approach for planar transistors and/or non-planar transistor architectures, such as for FinFET transistors, wherein superior process uniformity may be accomplished by planarizing a placeholder material in an early manufacturing stage, i.e., prior to actually patterning the placeholder gate electrode structures. To this end, any appropriate planarization techniques may be applied after depositing at least a portion of the placeholder electrode material. For example, on reliably filling any recesses caused by pronounced surface topography, for instance encountered between closely spaced active regions of planar transistor configurations due to the formation of a shallow trench isolation or between semiconductor fins of non-planar transistor configurations, which may be isolated by isolation regions that extend to certain height levels for adjusting the electrically effective height of the semiconductor fins, the resulting surface topography may be planarized, for instance, by CMP, etch techniques or a combination thereof so as to obtain a substantially planar surface topography, wherein, if desired, the further deposition may be continued so as to obtain a final thickness of the placeholder material. In other cases, the placeholder material may be deposited with a sufficient thickness, which may result in the desired target thickness after applying the planarization process in order to obtain the desired target thickness with a substantially planar surface topography.

In this respect, a “substantially planarized” surface topography of the placeholder material is to be understood that any differences in height level of the resulting surface of the placeholder material prior to the further processing may be less than fifty percent of the initial step height, while in some illustrative embodiments the planarization may result in a reduction in height that may be thirty percent or less of the initial step, while in other illustrative embodiments even a reduction to a step height of thirty percent and less may be achieved. For example, if difference in height levels between an isolation region formed in a space between semiconductor fins of a non-planar transistor and the top surface of the semiconductor fins is 30 nm, the step in height after depositing the placeholder material and planarizing the same, the resulting step in height measured at the same lateral position, may be 15 nm or less, while in superior applications this height difference may be 9 nm and less.

It should be appreciated that the principles disclosed herein may be advantageously applied to planar transistor configurations and to non-planar transistor configurations in which sophisticated high-k metal gate electrode structures are to be formed on the basis of a replacement gate approach. In this approach, at least the highly conductive electrode metal, such as aluminum, may be provided by replacing the placeholder material, for instance in the form of a polysilicon material and the like. In other illustrative embodiments, the replacement of the placeholder material may also include the incorporation of appropriate work function metal materials and/or the incorporation of a high-k dielectric material, which, however, may be provided in other illustrative embodiments in an early manufacturing stage.

It should further be appreciated that the principles disclosed herein may apply to any semiconductor devices in which planar transistors and non-planar transistors may commonly be provided, depending on the overall device requirements.

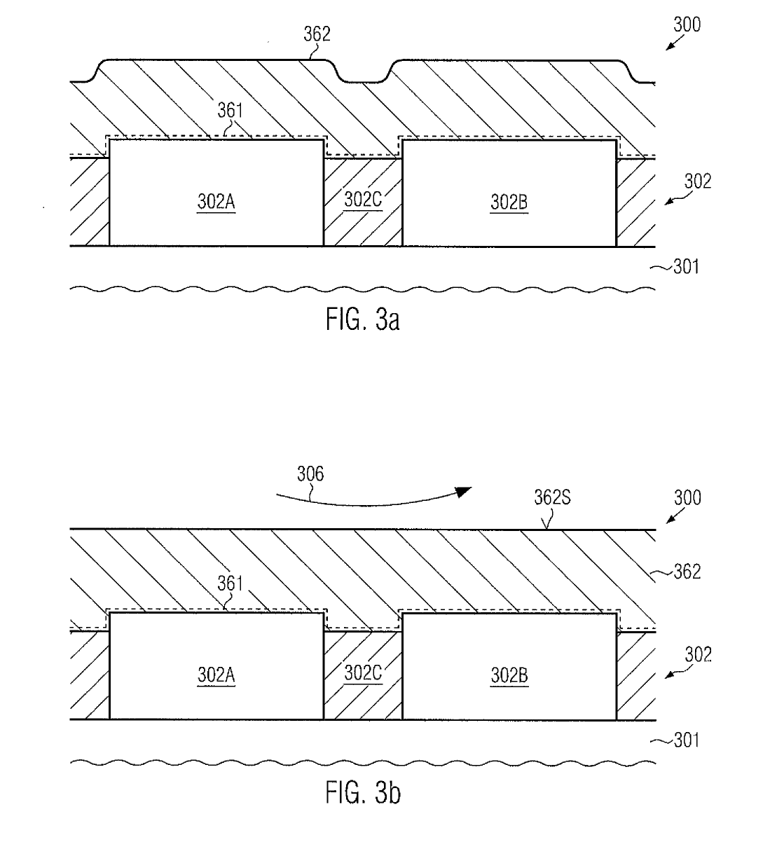

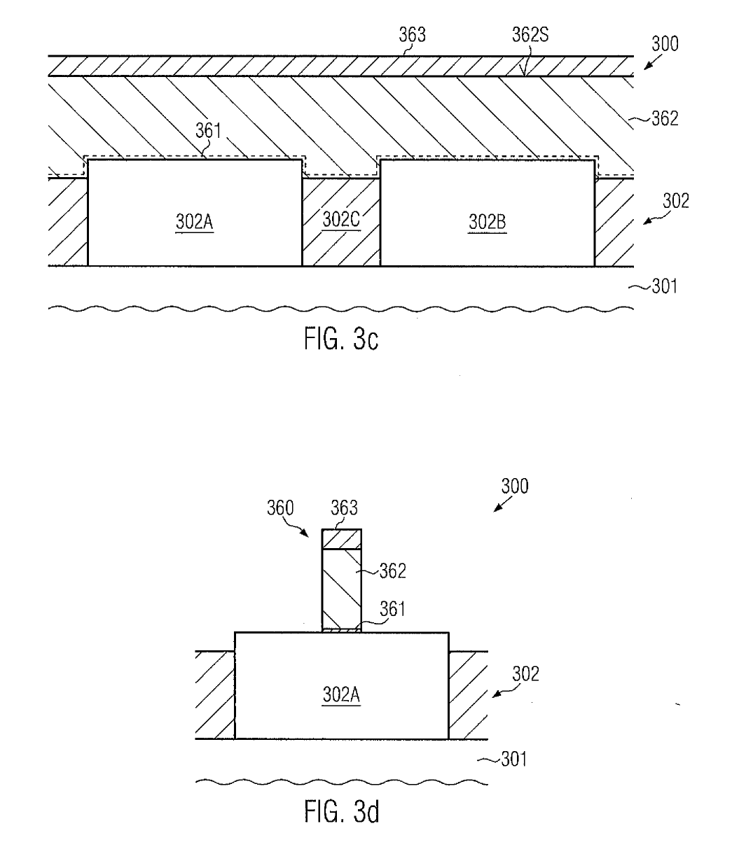

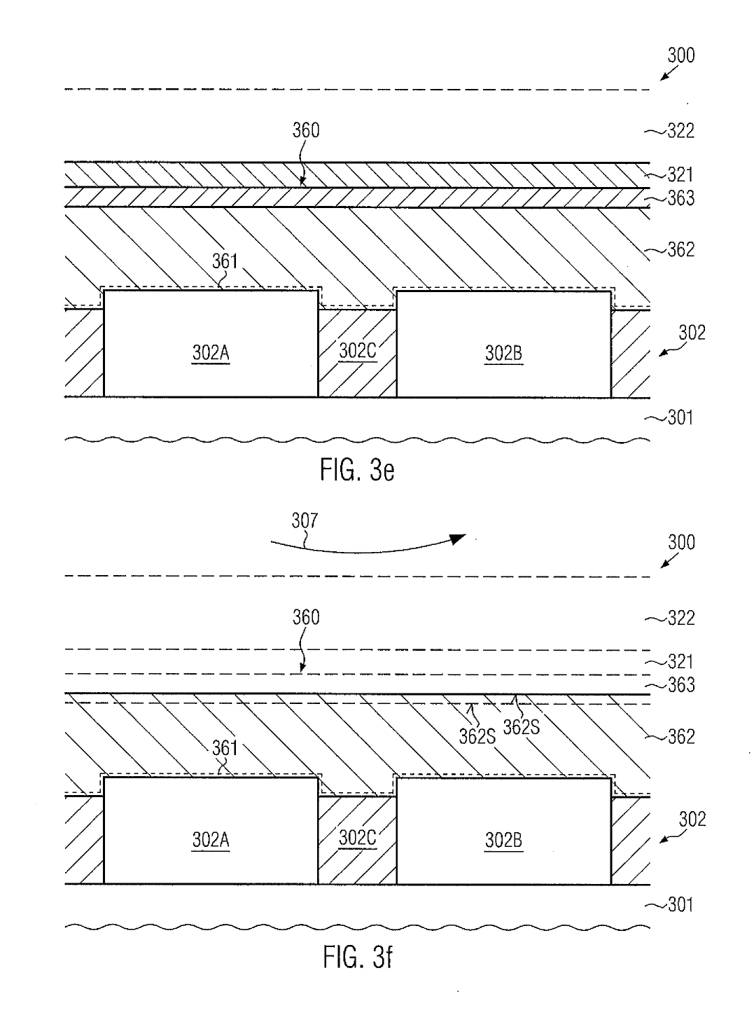

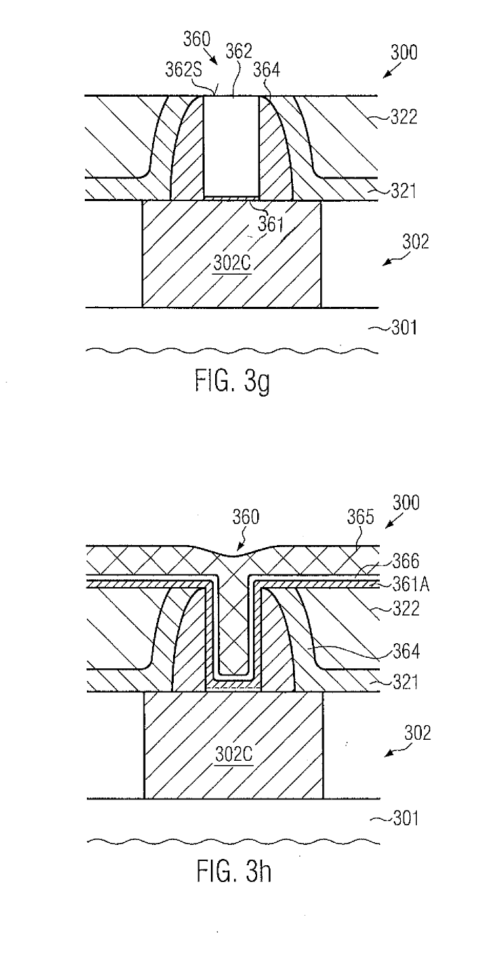

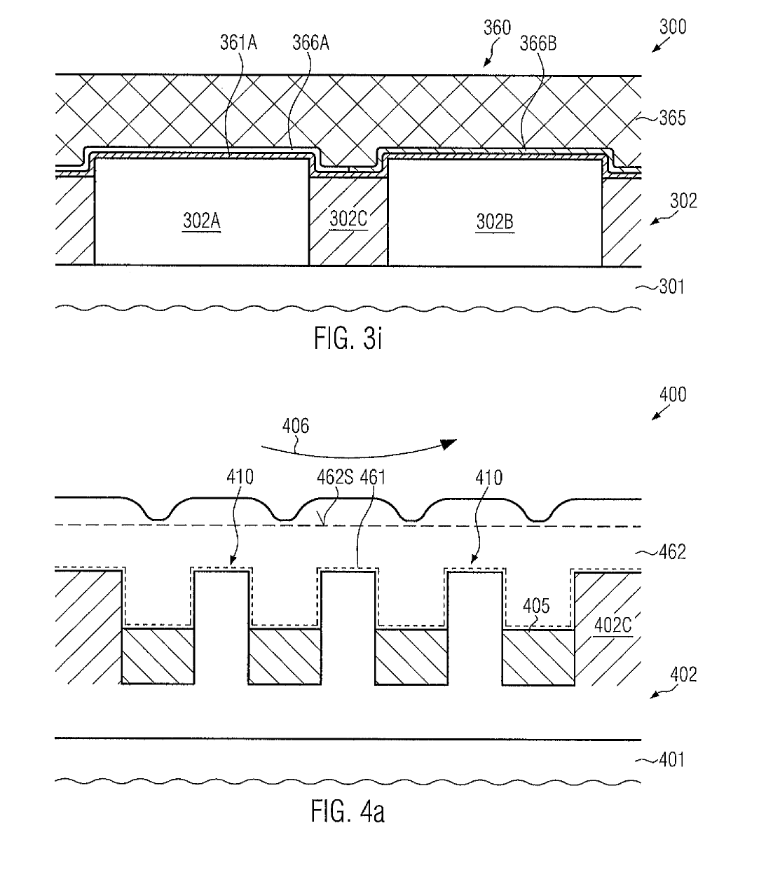

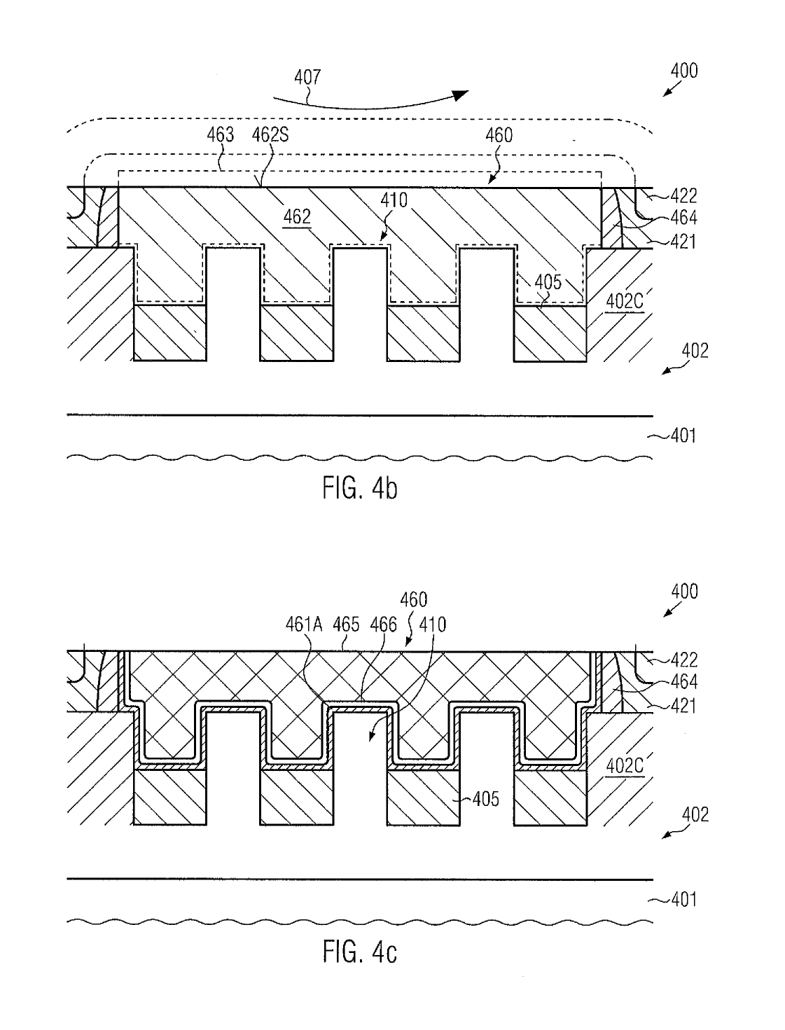

With reference to FIGS. 3a-3i and 4a-4c, further illustrative embodiments will now be described in more detail.

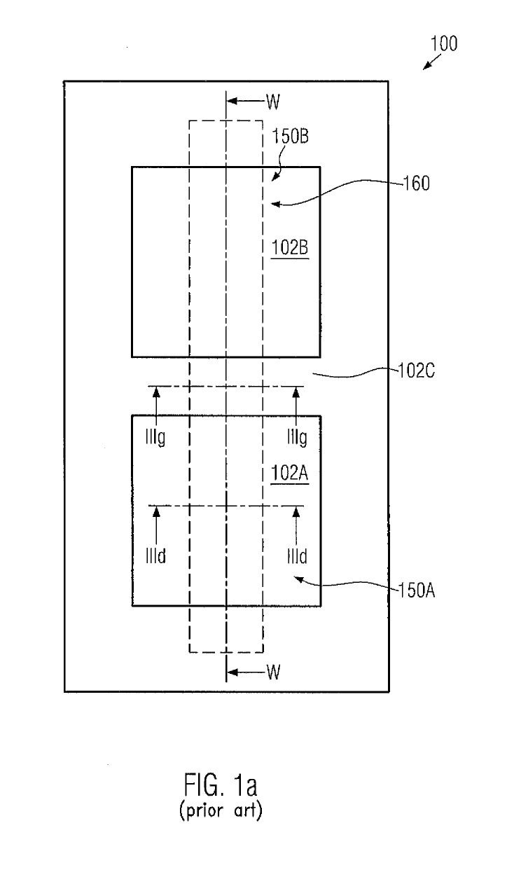

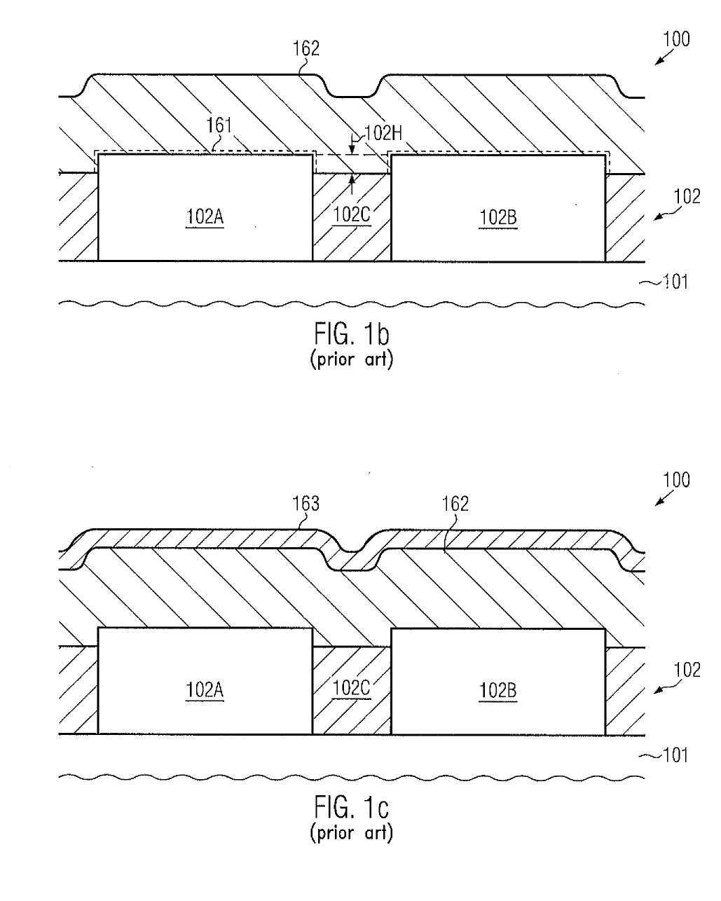

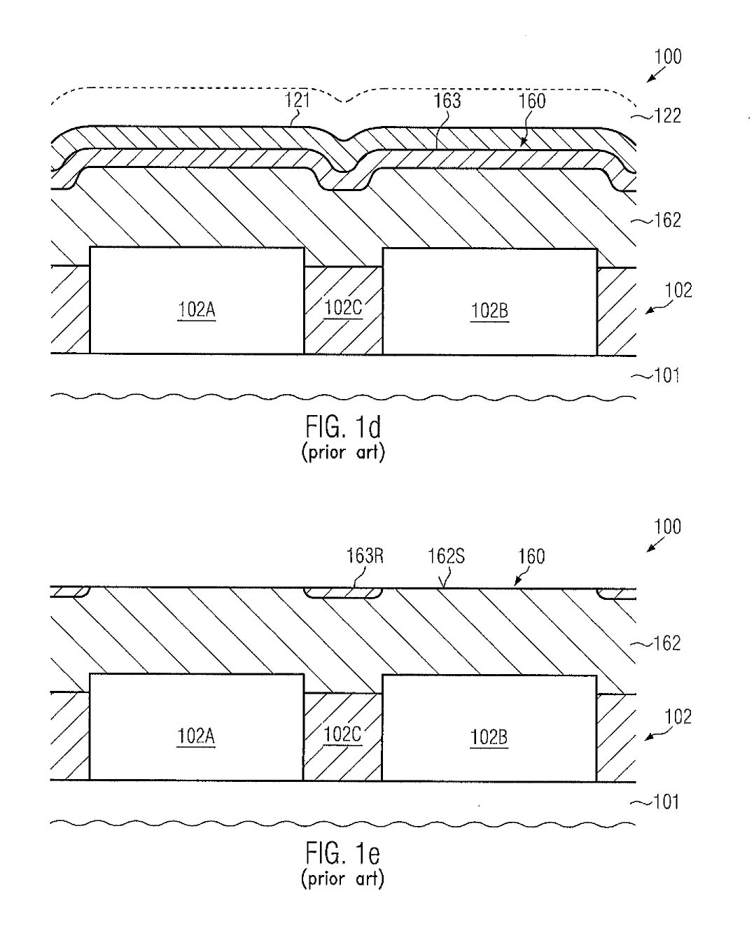

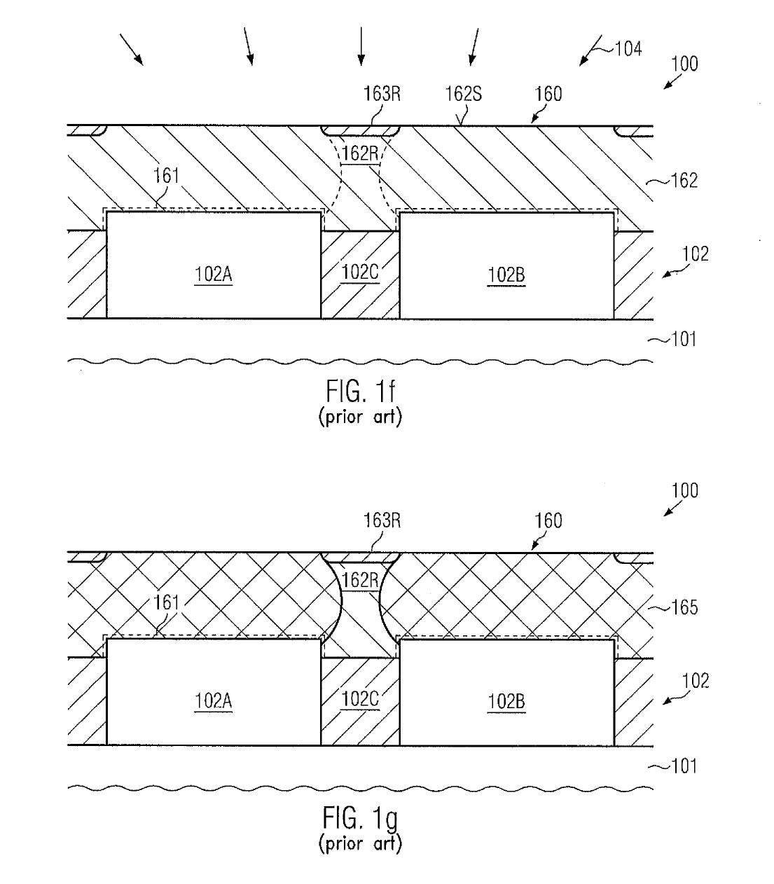

FIG. 3a schematically illustrates a cross-sectional view of a semiconductor device 300 in an early manufacturing stage. The cross-section of FIG. 3a may correspond to a cross-section as is also indicated in FIG. 1a and thus the horizontal direction in FIG. 3a may generally correspond to a transistor width direction of any transistors to be formed in and above active or semiconductor regions 302A, 302B, which may be formed in a semiconductor layer 302. Furthermore, an isolation region 302C, which may represent a shallow trench isolation, may laterally delineate and thus also separate the semiconductor regions 302A, 302B. With respect to these components, the same criteria may apply as previously explained with reference to the semiconductor device 100. Consequently, a certain difference in the height level between the semiconductor regions 302A, 302B on the one hand and the isolation region 302C on the other hand may exist owing to the previous manufacturing sequence for forming the isolation regions 302C. Furthermore, in the embodiment shown, a gate dielectric material 361 may be formed at least above any exposed surface areas of the semiconductor regions 302A, 302B and may be provided in the form of a silicon oxide-based material, possibly in combination with a high-k dielectric material, while in other cases a high-k dielectric material may be provided in a later manufacturing stage, for instance by replacing the layer 361 or at least a portion thereof. Moreover, a placeholder material 362, such as a polysilicon material, a silicon/germanium material, an amorphous silicon material or any other appropriate material which may allow appropriate patterning strategies to be applied in a later manufacturing stage, may be formed above the semiconductor layer 302.

The semiconductor device 300 may be formed on the basis of similar process techniques, as described above with reference to the semiconductor device 100. As discussed above, in some illustrative embodiments, the material 362 may be provided up to a first height level and may be subsequently planarized and thereafter the further processing may be continued so as to further deposit material in order to obtain a desired height level.

FIG. 3b schematically illustrates the device 300 during a planarization process 306, which in some illustrative embodiments includes a CMP process, which may be performed on the basis of well-established recipes, such as recipes used to planarize silicon-based materials. Consequently, a substantially planarized surface 362S may be obtained, thereby substantially eliminating or at least significantly reducing any height difference above the semiconductor regions 302A, 302B and above the isolation region 302C. As discussed before, if desired, an additional deposition process may be applied so as to further increase the thickness of the layer 362, if considered appropriate.

FIG. 3c schematically illustrates the device 300 in a further advanced manufacturing stage in which a dielectric cap layer or cap layer system 363 may be formed above the layer 362, wherein, as also discussed above, the layer or layer system 363 may also act as an efficient hard mask material for the patterning of the material 362 in a later manufacturing stage. Next, any sophisticated lithography and etch techniques may be applied so as to pattern the layers 363 and 362 in accordance with the overall design rules. For example, gate electrode structures with a gate length of 50 nm and less may have to be provided in the semiconductor device 300, thereby requiring sophisticated patterning strategies.

FIG. 3d schematically illustrates a cross-sectional view along a length direction, as for instance indicated by the line 111d in FIG. 1a. As shown, a gate electrode structure 360 comprising the patterned layers 363, 362 and 361 may be formed above the semiconductor region 302A and may have a desired lateral size, i.e., length and width as required by the overall design rules. It should be appreciated that in FIG. 3d the horizontal extension of the material 362 may substantially correspond to a gate length of the electrode structure 360. It should be appreciated that the final length of the structure 360 may be adjusted in a later manufacturing stage when, for instance, a dielectric material has to be formed so as to replace the layer 361 or complete the layer 361, depending on the overall process strategy. Thereafter, the further processing may be continued by performing processes such as the incorporation of drain and source dopant species into the active region 302A and into other active regions, followed by the formation of a sidewall spacer structure and the like, as may be required for completing the basic transistor configuration. Moreover, any high temperature processes may be applied as required and thereafter an interlayer dielectric material (not shown) may be deposited above the active region 302A, the isolation region 302C and the gate electrode structure 360.

FIG. 3e schematically illustrates the device 300 in a cross-sectional view along the width direction in a manufacturing stage in which an interlayer dielectric material or material system may be formed above and laterally adjacent to the gate electrode structure 360. For example, materials 321, 322 may be provided, for instance, in the form of silicon nitride, silicon dioxide and the like. Thus, the gate electrode structure 360 is embedded by the interlayer dielectric material, i.e., the materials 321, 322. To this end, any well-established deposition techniques may be applied.

FIG. 3f schematically illustrates the device 300 during a material removal process 307, which may comprise etch processes, CMP processes and the like, in order to remove an excess portion of the materials 321, 322 so as to finally expose a top surface 362S of the placeholder material 362. For example, in some illustrative embodiments, the process 307 may comprise a CMP process in which, in a final stage, the materials 322, 321 and 363 may be polished so as to locally expose the material 362 of the gate electrode structure 360. Due to the superior surface topography, the surface 362S may also be reliably exposed above the isolation region 302C. Moreover, during the process 307, a desired height level may be adjusted by appropriately controlling the process time of the process 307, as indicated by the dashed line, when the surface 362S is to be positioned at a lower height level. Due to the substantially planar surface topography of the gate electrode structure 360, any such height adjustment may be performed without any interference of remaining material residues or at least on the basis of significantly reduced residue materials.

FIG. 3g schematically illustrates a cross-sectional view of the device 300 according to a section as is indicated in FIG. 1a as section 111g. As shown, the gate electrode structure 360 is laterally embedded in the dielectric materials 321, 322 and may additionally comprise a spacer structure 364, depending on the overall process strategy for forming any transistors in the active regions 302A, 302B (FIG. 3f). Moreover, the surface 362S of the placeholder material 362 may be reliably exposed above the isolation region 302C due to the superior surface topography. The processing may then be continued by selectively removing the material 362, which may be accomplished on the basis of highly selective etch recipes wherein the layer 361 may be used as an etch stop material, in particular above the active regions 302A, 302B (FIG. 3f). Depending on the overall process strategy, additional cap or etch stop layers (not shown) may be provided above the layer 361, in particular when the material 361 may comprise a high-k dielectric material. In other cases, the layer 361 may be removed, at least partially, and a further gate dielectric material may be deposited after the removal of the placeholder material 362 so as to comprise a high-k dielectric material.

FIG. 3h schematically illustrates the device 300 in a further advanced manufacturing stage. As shown, a gate dielectric material 361A may be formed in the gate electrode structure 360 and may be a high-k dielectric material or may comprise a high-k dielectric material, depending on the overall process strategy. Furthermore, if required, a work function metal layer 366 may be provided so as to adjust work function of the gate electrode structure 360, at least above one of the active regions 302A, 302B, if these regions represent active regions of transistors of different conductivity type. Thus, the layer 366 may comprise a different metal species, possibly in combination with barrier materials and the like in portions of the gate electrode structure 360 which are formed above different active regions. Furthermore, a highly conductive electrode material 365, for instance in the form of aluminum, may be provided in the gate electrode structure 360.

The materials 361A, 366 and 365 may be provided on the basis of well-established deposition techniques, such as atomic layer deposition (ALD), CVD, sputter deposition, electrochemical deposition and the like. Thereafter, any excess material may be removed, for instance, by CMP and the like so as to finally form the gate electrode structure 360 as an electrically isolated structure that is laterally embedded in the materials 321 and 322.

FIG. 3i schematically illustrates the device 300 in a cross-sectional view along the width direction wherein the gate electrode structure 360 may comprise the materials 365, 361A and an appropriate work function adjusting metal species. For example a work function metal layer 366A may be formed above the active region 302A, while a work function adjusting metal species 366B may be provided above the active region 302B, possibly in combination with additional barrier materials so as to separate and thus block any other work function metal species from being positioned in the vicinity of the gate dielectric material 361A. Moreover, the highly conductive metal 365 may be reliably formed above the active regions 302A, 302B and above the isolation region 302C, thereby providing superior electrical performance of the gate electrode structure 360.

With reference to FIGS. 4a-4c, further illustrative embodiments will now be described in which a non-planar transistor configuration may be implemented on the basis of a replacement gate approach. It should be appreciated that the non-planar transistor may be provided together with planar transistors, such as the device 300, as considered appropriate.

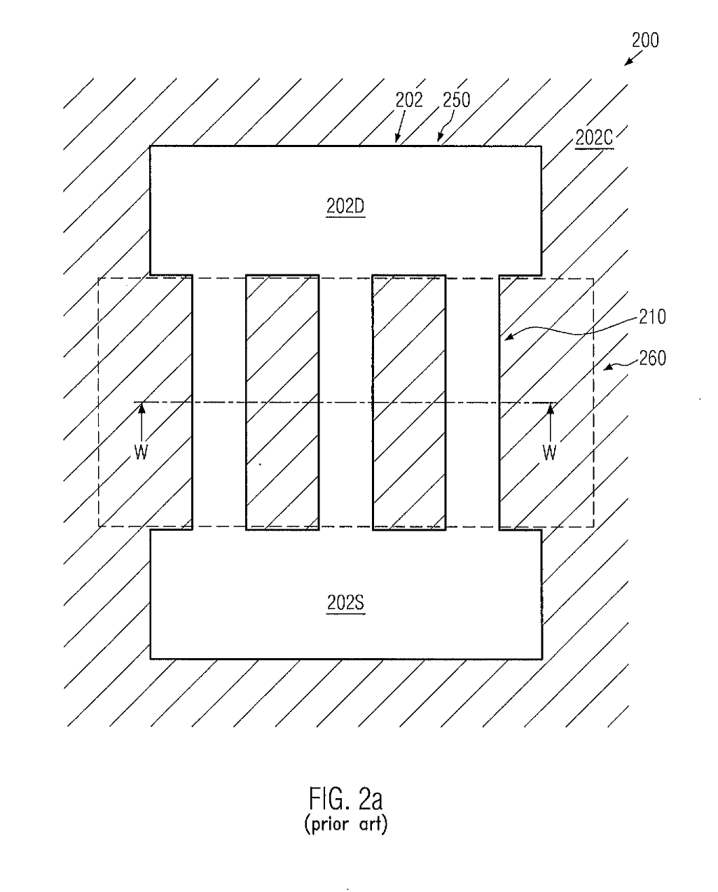

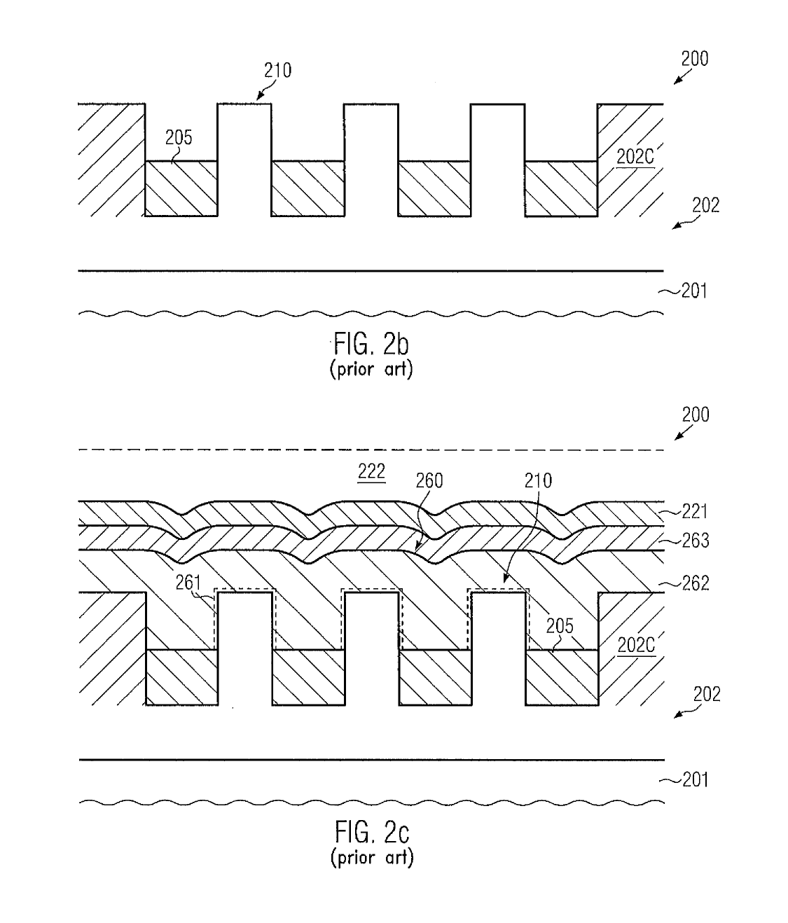

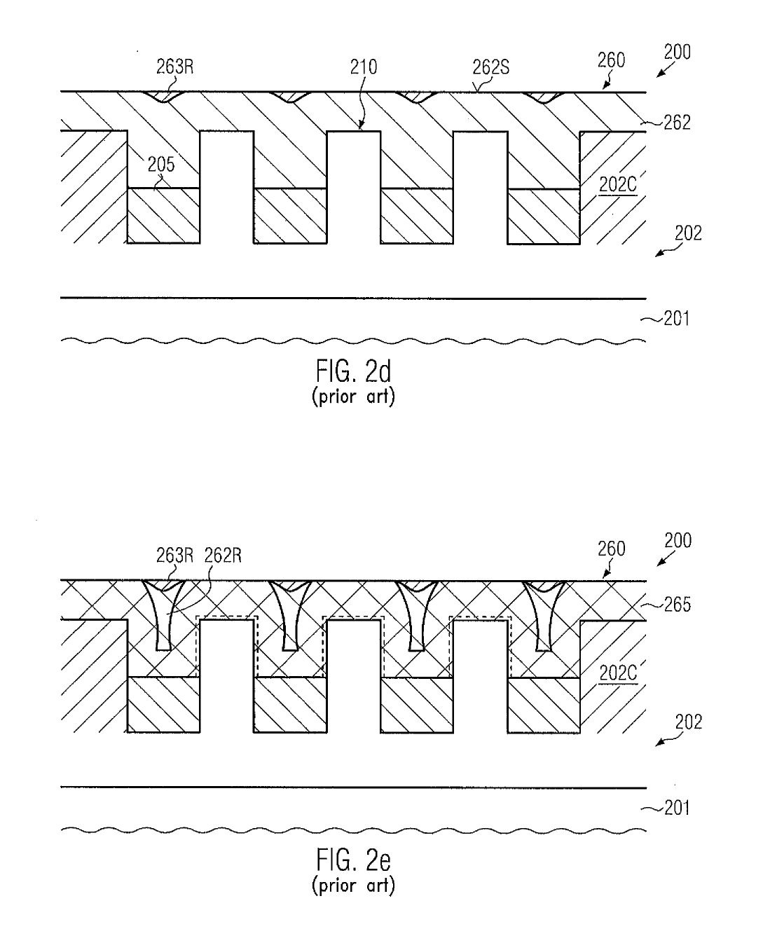

FIG. 4a schematically illustrates a semiconductor device 400 which may be a part of the device 300, as discussed above, while in other cases the device 400 may represent a separate semiconductor device. As illustrated, the device 400 may comprise a substrate 401 and a semiconductor layer 402, such as a silicon-based material and the like. Moreover, first isolation regions 402C may be formed in the semiconductor layer 402, for instance in the form of shallow trench isolations and the like. Moreover, second isolation regions 405 may be formed between semiconductor fins 410 and may extend to a defined height level so as to adjust the electrically effective height of the semiconductor fins 410. The semiconductor fins 410 may be provided as “stand alone” semiconductor fins, which may be connected at corresponding end portions after forming a gate electrode structure, while in other cases the fins 410 may have a similar configuration, as for instance shown in the top view of FIG. 2a when referring to the transistor 250. For example, the fins may have a lateral dimension, i.e., a width, in FIG. 4a the horizontal extension of the fins 410, of 15-30 nm, while a total height thereof may be 50 nm and less. On the other hand, the electrically effective height may be approximately 40-10 nm or less, depending on the overall device requirements. Consequently, the semiconductor fins 410 in combination with the isolation regions 405 may form a pronounced surface topography, as is also explained above with reference to the device 400. Furthermore, in the manufacturing stage shown, a dielectric layer 461, such as a silicon dioxide-based material, a high-k dielectric material and the like, may be formed so as to cover at least any exposed surface areas of the semiconductor fins 410. Moreover, a placeholder material 462 may be formed above the semiconductor layer 402 and thus also above the semiconductor fins 410 and between any spaces. For example, the placeholder material 462 may be provided in the form of a polysilicon material, amorphous silicon material or any other semiconductor material, or on the basis of a dielectric material as long as appropriate etch selectivity and patterning behavior is guaranteed for the further processing of the device 400. Due to the pronounced surface topography caused by the isolation regions 405 and the semiconductor fins 410, the material 462 may have a pronounced surface topography, as is also previously discussed. Moreover, the device 400 may be subjected to a planarization process 406 in order to form a planarized surface 462S, as indicated by the dashed line. To this end, the planarization process 406 may comprise a CMP process, an etch process, or any combination thereof. Furthermore, as also discussed above with reference to the semiconductor device 300, the planarization process 406 may be performed at any intermediate stage followed by a further deposition, wherein a corresponding sequence of a planarization step of a subsequent deposition step may be applied twice or more, in order to provide superior uniformity of the resulting surface 462S.

FIG. 4b schematically illustrates the semiconductor device 400 in a further advanced manufacturing stage. As shown, a gate electrode structure 460 may be patterned from the materials 461, 462, which may be accomplished on the basis of a dielectric cap layer 463 or layer system, which may also act as a hard mask material during the corresponding lithography and patterning process strategy for patterning the gate electrode structure 460. After the patterning of the gate electrode structure 460, additional processes may be applied, for instance by forming spacer elements 464 and incorporating any appropriate dopant species into end portions of the semiconductor fins 410 (not shown), as required for forming a corresponding non-planar transistor. Moreover, any high temperature processes may be applied and thereafter an interlayer dielectric material or material system, for instance in the form of materials 421 and 422, may be deposited on the basis of any well-established deposition techniques, as is also discussed above. Next, a removal process 407 may be applied so as to remove any excess material and finally expose a surface 462S of the placeholder material 462 of the gate electrode structure 460. Due to the superior surface topography obtained by the previous planarization process 406 (FIG. 4a), undue material residues may be efficiently removed during the process 407 so that the surface 462S may also be exposed above the isolation regions 405.

FIG. 4c schematically illustrates the semiconductor device 400 in a further advanced manufacturing stage. As illustrated, the gate electrode structure 460 may comprise a highly conductive electrode material 465, possibly in combination with a work function adjusting metal species 466, while in the embodiment shown also a gate dielectric material 461A may be formed so as to include a high-k dielectric material. To this end, any well-established process techniques may be applied, i.e., the material 462 (FIG. 4b) may be removed on the basis of selective etch recipes and also the material 461, if provided, may be removed or at least partially removed followed by the formation of the gate dielectric material 461A and the work function metal layer 466. Finally, the material 465 may be deposited and any excess material may be removed, for instance by CMP and the like.

As a result, the present disclosure provides manufacturing techniques for forming sophisticated high-k metal gate electrode structures for planar and non-planar transistor configurations according to replacement gate approaches, wherein superior process uniformity and thus device uniformity may be achieved by implementing at least one planarization step after the deposition of the placeholder material and prior to actually patterning the placeholder material.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a layer of a placeholder material above a semiconductor layer of a semiconductor device, said semiconductor layer comprising a first semiconductor region and a second semiconductor region that are laterally separated by an isolation region;
performing a planarization process so as to form a planarized surface on said layer of a placeholder material;
forming a placeholder electrode structure from at least said layer of a placeholder material, said placeholder electrode structure being formed above said first and second semiconductor regions and said isolation region; and
replacing said placeholder material of said placeholder electrode structure at least with a conductive electrode material so as to form a gate electrode structure.

2. The method of claim 1, wherein forming a placeholder electrode structure comprises forming a dielectric cap layer above said layer of a placeholder material after performing said planarization process.

3. The method of claim 2, wherein replacing said placeholder material comprises removing said dielectric cap layer from said placeholder material by performing a removal process in the presence of a fill material formed laterally adjacent to said placeholder electrode structure.

4. The method of claim 1, further comprising forming an interlayer dielectric material at least laterally adjacent to said placeholder material and wherein said placeholder material is replaced in the presence of said interlayer dielectric material.

5. The method of claim 4, wherein said interlayer dielectric material is formed above said placeholder material and wherein replacing said placeholder material comprises planarizing said interlayer dielectric material so as to expose a surface of said placeholder material and removing said placeholder material selectively to said interlayer dielectric material.

6. The method of claim 5, wherein planarizing said interlayer dielectric material comprises performing a polishing process.

7. The method of claim 1, wherein replacing said placeholder material at least with a conductive electrode material further comprises forming a high-k dielectric material prior to forming said conductive electrode material.

8. The method of claim 1, further comprising forming said isolation region in said semiconductor layer so as to laterally delineate said first and second semiconductor regions by a shallow trench isolation.

9. The method of claim 1, further comprising forming said first and second semiconductor regions by forming a first fin and a second fin from said semiconductor layer.

10. The method of claim 9, wherein said first and second fins are formed so as to extend to a height level that is above a height level of a top surface of said isolation region.

11. The method of claim 1, wherein said placeholder material is formed by depositing a semiconductor material.

12. A method of forming gate electrode structures, the method comprising:
forming a placeholder material above a first semiconductor region, a second semiconductor region and an isolation region that laterally delineates said first and second semiconductor regions;
planarizing said placeholder material so as to form a substantially planarized surface of said placeholder material above said first and second semiconductor regions and above said isolation region;
patterning said placeholder material having said substantially planarized surface so as to form a placeholder electrode structure;
forming an interlayer dielectric material above said placeholder material;
performing a material removal process so as to expose a top surface of said placeholder material; and
replacing said placeholder material at least with an electrode material.

13. The method of claim 12, further comprising forming at least one dielectric cap layer above said placeholder material having said substantially planarized surface.

14. The method of claim 12, wherein planarizing said placeholder material comprises performing a chemical mechanical polishing process.

15. The method of claim 12, wherein performing said material removal process comprises performing a planarization process.

16. The method of claim 13, wherein patterning said placeholder material comprises using one or more of said at least one dielectric cap layer as a hard mask.

17. The method of claim 12, wherein replacing said placeholder material at least with an electrode material further comprises forming a high-k dielectric material after removing said placeholder material and prior to forming said electrode material.

18. A method, comprising:
forming a plurality of semiconductor fins so as to be laterally separated by isolation regions, said plurality of semiconductor fins extending to a first height level, said isolation regions extending to a second height level that is less than said first height level;
forming a placeholder material above said plurality of semiconductor fins and said isolation regions;
planarizing said placeholder material;
patterning said planarized placeholder material so as to form a placeholder electrode structure;
forming an interlayer dielectric material above said placeholder electrode structure;
exposing a top surface of said placeholder material; and
replacing said placeholder material at least with an electrode material.

19. The method of claim 18, wherein exposing said top surface comprises performing a planarization process.

20. The method of claim 18, wherein replacing said placeholder material at least with an electrode material comprises forming a high-k dielectric material in said placeholder electrode structure prior to forming said electrode material.
